(19) United States
(12) Patent Application Publication
(10) Pub. No.: US 2013/0255775 A1
(43) Pub. Date: Oct. 3, 2013

(54) WIDE BAND GAP PHOTOVOLTAIC DEVICE AND PROCESS OF MANUFACTURE

(71) Applicant: NUSOLA, INC., Burlingame, CA (US)

(72) Inventors: Kuniaki Shida, Nagaoka-Shi (JP); Daisuke Okumura, Nagaoka-Shi (JP); Jose Briceno, Ohta-ku (JP)

(21) Appl. No.: 13/844,747

(22) Filed: Mar. 15, 2013

Related U.S. Application Data
(60) Provisional application No. 61/722,693, filed on Nov. 5, 2012.
(60) Provisional application No. 61/738,375, filed on Dec. 17, 2012.
(60) Provisional application No. 61/619,410, filed on Apr. 2, 2012.

(51) Int. Cl. H01L 31/18; H01L 31/0352

(52) U.S. Cl. CPC H01L 31/1872; H01L 31/035272
USPC 136/256; 438/94

(57) ABSTRACT

A wide band gap, heterojunction photovoltaic material comprises a bulk layer, a high-resistivity layer and a microcrystalline silicon carbide layer. The heterojunction semiconductor material is formed by heating a single-piece semiconductor material to form a high-resistivity layer over a bulk layer, the high-resistivity layer having SiC seed crystals at the top surface. A layer of SiC is sputtered over the high-resistivity layer, and the structure is annealed. The annealing and the SiC seed crystals causes the sputtered SiC layer to convert into a microcrystalline β-SiC layer. When the layer of SiC is sputtered using a p-type SiC target, a p-type SiC layer is formed over the high-resistivity layer. The heterojunction material may exhibit photovoltaic properties. Applications include forming a photovoltaic device with the heterojunction material.

### CROSS-REFERENCE TO RELATED APPLICATIONS

This application claims the benefit of U.S. Provisional Application No. 61/738,375, entitled “Wide Band Gap Photovoltaic Device and Process of Manufacture,” filed Dec. 17, 2012 (Ref. No. P5) U.S. Provisional Application No. 61/722,693, entitled “Photovoltaic Cell and Methods for Manufacture,” filed Nov. 5, 2012 (Ref. No. P3), and U.S. Provisional Application No. 61/619,410, entitled “Single-Piece Photovoltaic Device,” filed Apr. 2, 2012 (Ref. No. P2).

This application is related to copending U.S. application Ser. No. 13/---, “Single-Piece Photovoltaic Device,” filed on even date herewith (Ref. No. P2), and U.S. application Ser. No. 13/---, “Photovoltaic Cell and Methods for Manufacture,” filed on even date herewith (Ref. No. P3) , the entireties of which are incorporated by reference as if fully set forth herein.

### FIELD OF THE INVENTION

The present invention relates generally to photovoltaic conversion, and more particularly, to a highly-efficient photo-voltaic conversion solar cell formed from a wide band gap heterojunction design.

### BACKGROUND OF THE INVENTION

Solar cell technology has been introduced in response to a trend toward environmental protection and energy saving. Large megawatt-class solar farms have been developed and have become more and more popular around the world. Current or legacy solar cell technology utilizes crystalline silicon as a main component, and in some other cases, inexpensive poly-crystalline silicon or other compound semiconductors. In addition, other technologies utilize organic materials for the so-called dye-sensitized solar cell.

In some approaches, crystalline silicon solar cells are fabricated by means of forming a high concentration n-type layer on a p-type silicon substrate. This high concentration n-type layer is generally formed by a process of ion implantation, or diffusion, by introducing the n-type dopant phosphorus to form a P-N junction, followed by an annealing process. Once the P-N junction is so formed, anode and cathode electrodes are formed to complete a photo-voltaic cell.

When the photo-voltaic layer having a silicon P-N junction is formed, the theoretical maximum value of the open circuit voltage (V_{OC}), an index showing performance, is limited to less than 600 mV, thus limiting the performance or efficiency of such photo-voltaic cells. In order to improve photo-voltaic cell performance, it is therefore necessary to form a material for obtaining a higher open circuit voltage.

Approaches using a wide band gap heterojunction design are used for obtaining a higher open circuit voltage. In such approaches, epitaxy is used to deposit a crystalline layer on a crystalline substrate, and requires a processing temperature of approximately 2100 K.

Such approaches result in a high cell unit cost due to several factors. The cost of a photo-voltaic cell is dependent on the semiconductor wafer cost. As photo-voltaic cells cannot be miniaturized by using smaller fabrication geometries, their cost is dependent on the physical size or area of the cell and on the cost of the underlying manufacturing process.

Further, the extremely high temperature processing limits wafer size to up to four inches per treatment, resulting in a cell unit cost increase. It is desirable to achieve higher open circuit voltage output in a photo-voltaic cell using a wide band gap heterojunction design while lowering the cell unit cost.

The approaches described in this section are approaches that could be pursued, but not necessarily approaches that have been previously conceived or pursued. No admissions are being made by virtue of their inclusion in this section.

### BRIEF SUMMARY OF PREFERRED EMBODIMENTS OF THE INVENTION

Preferred embodiments of the invention provide a novel method of manufacturing a new material with photovoltaic properties. Embodiments of the new material have a wide band gap heterojunction design using two semiconductors, such as single-crystal silicon layer and a silicon carbide layer.

### BRIEF DESCRIPTION OF THE DRAWINGS

Preferred embodiments of the present invention are illustrated by way of example, and not by way of limitation, in the figures of the accompanying drawings and in which like reference numerals refer to similar elements and in which:

FIG. 1 is a diagram illustrating a cross section of the semiconductor material during a heating stage of the manufacturing process, according to one or more embodiments of the invention.

FIG. 2 is a diagram illustrating a cross section of the semiconductor material of one stage of the manufacturing process after the heating, according to one or more embodiments of the invention.

FIG. 3 is a diagram illustrating a cross section of the semiconductor material of one stage of the manufacturing process during sputtering, according to one or more embodiments of the invention.

FIG. 4 is a diagram illustrating a cross section of the semiconductor material during one stage of the manufacturing process after sputtering, according to one or more embodiments of the invention.

FIG. 5 is a diagram illustrating a cross section of a photovoltaic structure formed by the process described with reference to FIGS. 1 to 4, according to one or more embodiments of the invention.

FIG. 6 is a diagram illustrating a cross section as assembled into a photovoltaic cell, according to one or more embodiments of the invention.

FIG. 7 is a flow diagram illustrating a process for manufacturing photovoltaic material, according to one or more embodiments of the invention.

### DETAILED DESCRIPTION OF PREFERRED EMBODIMENTS OF THE INVENTION

In the following description numerous specific details have been set forth to provide a more thorough understanding of embodiments of the present invention. It will be appreciated however, by one skilled in the art, that embodiments of the invention may be practiced without such specific details or with different implementations for such details. Additionally some well known structures have not been shown in detail to avoid unnecessarily obscuring the present invention.

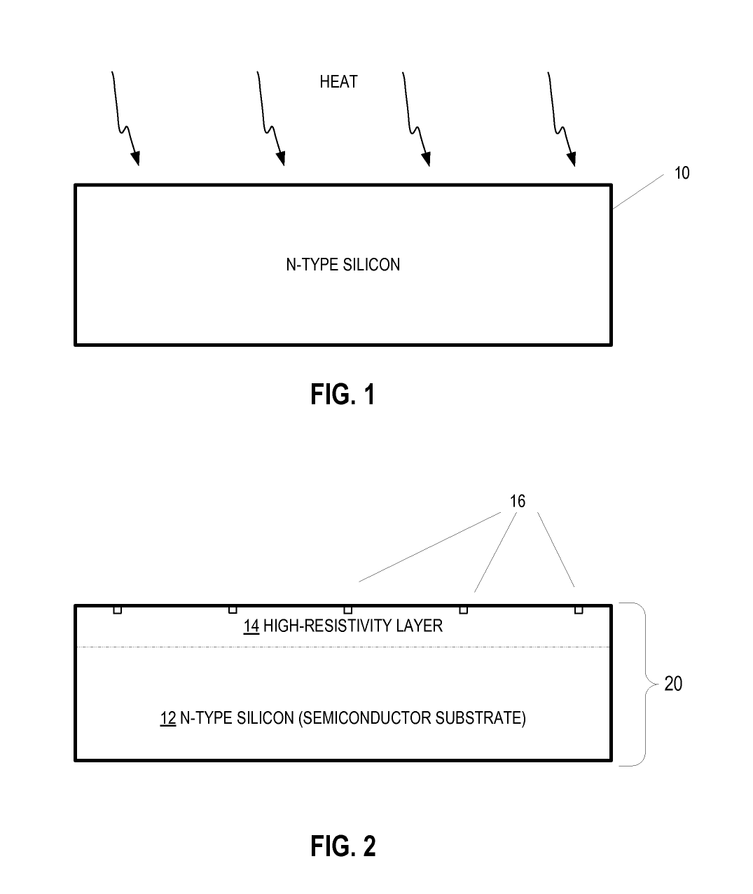

Other and further features and advantages of the present invention will be apparent from the following descriptions of the various embodiments when read in conjunction with the accompanying drawings. It will be understood by one of ordinary skill in the art that the following embodiments and illustrations are provided for illustrative and exemplary purposes only, and that numerous combinations of the elements of the various embodiments of the present invention are possible. Further, certain diagrams are not to scale and are provided to show structures in an illustrative manner. Exemplary wide band gap photovoltaic devices and process for manufacturing such devices according to preferred embodiments of the invention are described with reference to the accompanying figures, beginning with FIG. 1.

FIG. 1 to FIG. 4 are diagrams showing cross-sectional views during several stages of manufacture of a photovoltaic device, according to some embodiments of the invention. FIG. 1 is a diagrammatic view of a cross section of the semiconductor material as it is heated, or annealed, during the manufacturing process according to some embodiments of the invention. According to preferred embodiments, semiconductor substrate 10 is a 6-inch n-type single-crystal silicon wafer having a resistivity of 1 to 5 Ω·cm, having a crystal orientation of (100). In some embodiments, the crystal orientation may be (110) or (111), and solar grade silicon or poly-crystalline silicon may be used. Silicon substrates having different resistivities require different heating temperatures and times. Other wafer sizes may be also be used.

In some examples, semiconductor substrate 10 is cleaned prior to the annealing stage. Processes for cleaning include techniques such as the standard RCA cleaning method for semiconductors. In one example, cleaning begins with removing organic material using sulfuric acid-hydrogen peroxide water cleaning for ten minutes at 350 K. Next, pure water cleaning is performed, followed by nitrogen blow drying with infrared and ultraviolet light drying, followed by cleaning by a 0.5% hydrofluoric acid solution. Next, cleaning by ammonium-hydrogen peroxide water at 350 K for 10 minutes is performed. After pure water rinsing, heavy metal contamination is removed by cleaning in hydrochloric acid-hydrogen peroxide water cleaning at 80° C. for ten minutes. Lastly, a step of pure water cleaning and nitrogen gas drying are performed, followed by paper IPA drying.

In a preferred embodiment, during the heating stage, semiconductor substrate 10 is positioned in a vacuum and subject to a predetermined annealing temperature for a sufficient period of time to effectuate transformation of semiconductor substrate 10 to form first intermediate material 20, as shown in FIG. 2. In one example, the pressure is approximately 2E-4 Pa, and subject to temperatures of 1500 K or more, in a chamber having an inert gas, with semiconductor substrate 10 maintained in these conditions for approximately 30 minutes. While a vacuum of approximately 2E-4 Pa is used in the present example, the degree of vacuum may vary. For example, the vacuum may be 20 Pa or lower. Examples of inert gases by include argon gas, helium gas, or other inert gases, or a mixture of one or more of such gases.

In further reference to FIG. 2, first intermediate material 20 is composed of at least n-type single-crystal silicon layer 12, high resistivity layer 14, and silicon carbide (SiC) seed crystals 16 at the surface. In preferred embodiments, SiC seed crystals form in a thickness of approximately 2 to 5 nm at the surface as a result of the annealing stage. While diagrams such as FIG. 2 may show discrete boundaries between components of first intermediate material 20, it is understood by one of skill in the art that such boundaries may be blended and having some thickness of blended material without departing from the spirit of the invention. The characteristics of individual components, such as the thickness of high resistivity layer 14, and the number and location of SiC seed crystals formed by carbon segregation and migration to the surface, change depending on the pressure, temperature and time of the heating. In preferred embodiments, the resistivity of high resistivity layer 14 is at least ten times greater than the resistivity of n-type single-crystal silicon layer 12.

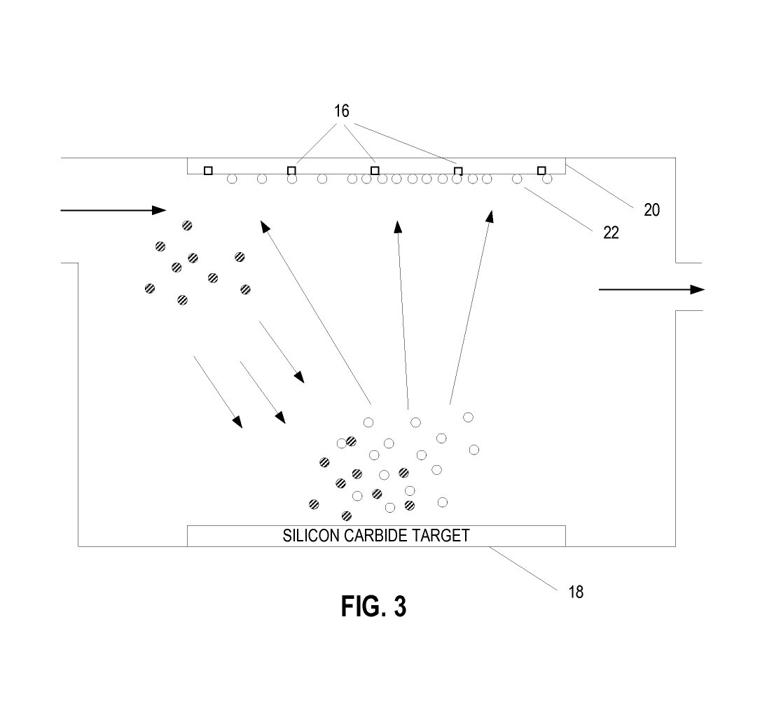

FIG. 3 is a diagram illustrating a cross section view of a sputtering stage that occurs after the annealing stage, according to some embodiments of the invention. Silicon carbide target 18 is used to deposit a layer of SiC 22 (shown in FIG. 3 as partially formed) onto first intermediate material 20 at the surface where seed crystals 16 were formed during the annealing process. In this example, SiC layer 22, when formed by the sputtering process, will have a thickness of approximately 10 nm. While the thickness of 10 nm is used in the present example, the thickness of layer 22 is not limited to 10 nm as long as the thickness allows light transmission through SiC layer 22. Further, while the silicon carbide was formed by the sputtering method in the present example, SiC layer 22 may be formed by methods including vacuum evaporation using electron beam or the like, or pulsed laser evaporation such as PLD, CVD, or the like.

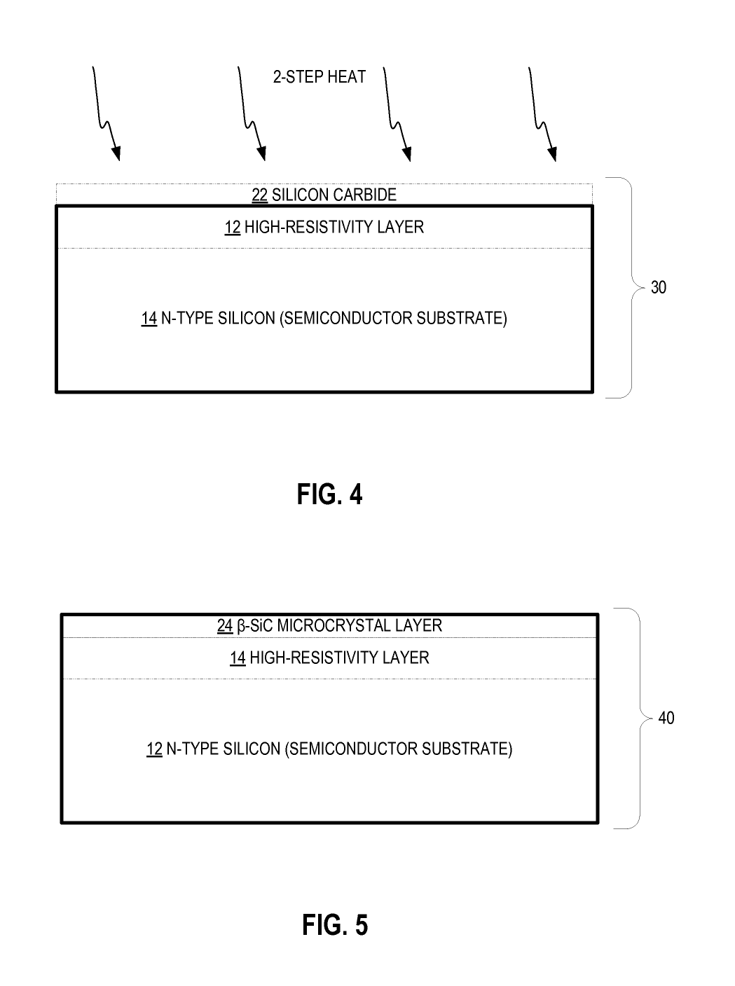

FIG. 4 is a diagram illustrating a cross section view of a second annealing process on second intermediate material 30, which is produced after the sputtering stage described above, according to some embodiments of the invention. Second intermediate material 30 is composed of at least n-type single-crystal silicon layer 12, high resistivity layer 14, and the SiC layer 22. The second annealing process comprises two phases. In a first phase, annealing occurs at a particular temperature to induce the conversion of SiC layer 22 into crystallized form. The presence of seed crystals 16 on first intermediate material 20 allows for microcrystals of SiC to form from the sputtered SiC layer 22 when a particular annealing temperature is applied in a first phase of annealing of second intermediate material 30. In a preferred embodiment, the first phase of the annealing process occurs at an annealing temperature of 1300 K for a duration of approximately two hours in inert gas. This phase converts the sputtered SiC layer 22 into a layer of microcrystalline β-SiC. The first phase is followed consecutively by a second phase of the annealing process at a lower temperature than the first phase, which produces a reduction in crystalline defects in the microcrystal layer. In a preferred embodiment, the second phase of the anneal process occurs at an annealing temperature of 900 K.

FIG. 5 is a diagram illustrating a cross section view of photovoltaic structure 40 formed by the process described with reference to FIGS. 1 to 4, according to some embodiments of the invention. Photovoltaic structure 40 is composed of at least n-type single-crystal silicon layer 12, high resistivity layer 14, and β-SiC microcrystal layer 24. β-SiC is a wide bandgap material having a bandgap of approximately 2.2 eV. The interface between n-type single-crystal silicon layer 12 and β-SiC microcrystal layer forms a heterojunction, thereby photovoltaic structure 40 forms a heterojunction semiconductor having photovoltaic properties.

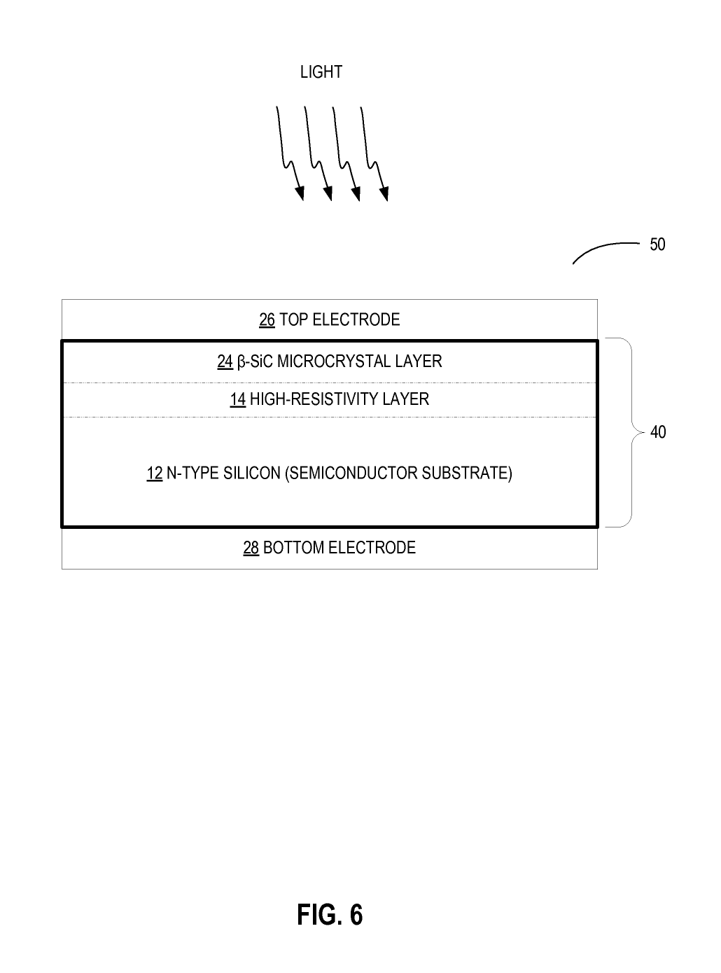

FIG. 6 is a diagram illustrating a cross section view of photovoltaic structure 40 assembled and functioning as photovoltaic cell 50, according to some embodiments of the invention. A transparent conductive film was formed over β-SiC microcrystal layer 24 as top electrode 26. In a preferred embodiment, a ZnO transparent conductive film having a thickness of 150 nm was formed over β-SiC microcrystal layer 24 by a sputtering method. While ZnO was used in the present example, another transparent conductive oxide films such as ITO, AZO, GZO, IZO, and NbO₂ or a stacked structure thereof may be used. Further, while the sputtering method is described as used for this example, the transparent conductive oxide film may be formed by PLD, MOCVD, or a coating method, not limited to the sputtering method.

To improve performance of the photovoltaic cell, a silicon nitride film may be formed as an anti-reflection film over top electrode 26. As bottom electrode 28, an Al was coated by printing to bottom surface and heating was provided at 550 K for removing binder. The addition of bottom electrode 28 completes construction of solar cell 50.

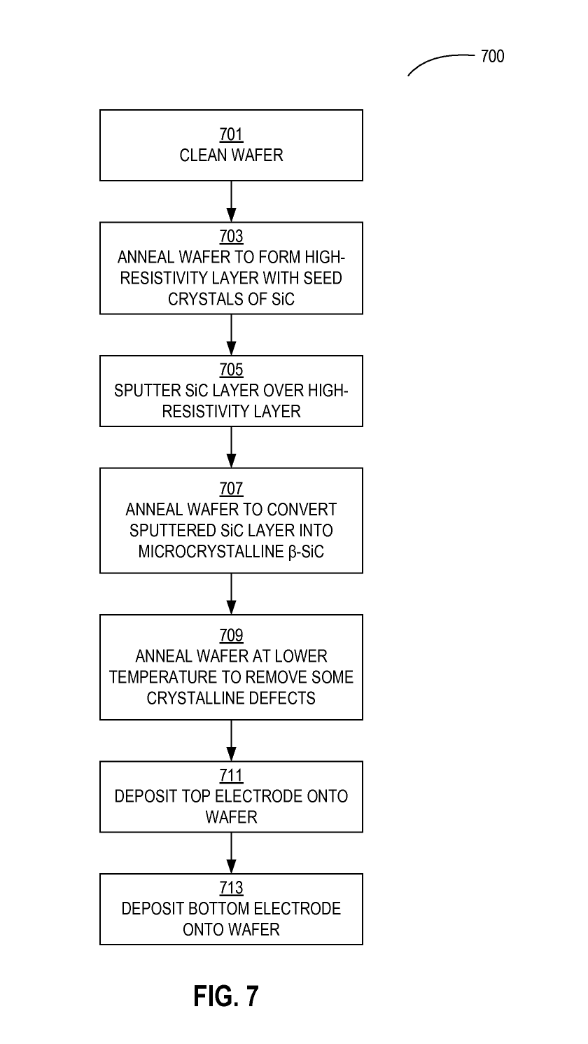

FIG. 7 is a flow diagram illustrating a process 700 for manufacturing a photovoltaic material, according to some embodiments of the invention. At step 701, a semiconductor substrate, such as n-type silicon substrate 10 described above with reference to FIG. 1, is cleaned according to standard methods for cleaning semiconductors prior to manufacturing, such as the RCA cleaning method. At step 703, the semiconductor substrate wafer is heated to anneal and form a first intermediate wafer material comprising a layer of the original semiconductor substrate material, over which is formed a high-resistivity layer with silicon carbide seed crystals at the surface, as illustrated in FIGS. 1 and 2.

At step 705, the first intermediate wafer material is coated with a layer of silicon carbide by sputtering with a silicon carbide target or by other deposition methods, forming a second intermediate wafer material. The second intermediate wafer material is annealed in two phases, as shown in FIG. 4. At step 707, at the first annealing phase, the wafer is heated to convert the deposited silicon carbide layer into a microcrystalline β-SiC layer. The conversion of the deposited SiC into microcrystalline β-SiC is possible due to the seed crystals that were formed after step 703. In a preferred embodiment, step 707 is performed at a temperature of approximately 1300 K for approximately 2 hours. At step 709, at the second annealing phase, the wafer material is heated at a lower temperature to remove crystalline defects. In a preferred embodiment, step 709 is performed at a temperature of approximately 900 K for approximately one hour.

The next steps are performed to complete the assembly of the wafer material into a photovoltaic cell. At step 711, a top electrode is deposited over the β-SiC layer. At step 713, a bottom electrode is deposited or printed onto the bottom of the n-type silicon semiconductor substrate. Steps 711 and 713 may be performed using techniques described above with reference to FIG. 6.

The process of manufacture described above with reference to FIGS. 1 to 7 may be adapted for use with different materials to produce a photovoltaic structure. In some alternative embodiments, a p-type SiC layer is formed over high-resistivity layer 14 by the following adaptations. In this example, the first annealing process, as described with reference to FIG. 1, is performed at 1500 K. The sputtering process, as illustrated in FIG. 3, is performed with a SiC target having 80 ppm of aluminum to function as a p-type dopant. Following the sputtering, the remaining steps of the process proceed as described. This type of p-type conversion may also be obtained by a SiC sputtering target containing boron or gallium.

According to one or more embodiments, a solar cell comprises a first electrode layer, a photo-voltaic conversion layer, a silicon semiconductor substrate, and a second electrode formed therein as needed, wherein the photo-voltaic conversion layer is formed of at least two or more layers of semiconductors, a first high-resistivity photo-voltaic conversion layer, which is formed at a surface of the semiconductor substrate, and includes silicon material having a resistivity different from that of the silicon semiconductor substrate, and a second photo-voltaic conversion layer, which is formed over the first high-resistivity photo-voltaic conversion layer, and consists of a material having a band gap greater than a band gap of the silicon semiconductor substrate. In some embodiments, the first high-resistivity photo-voltaic conversion layer of the solar cell has a resistivity that is at least ten times greater than a resistivity of the silicon semiconductor substrate, and the second photo-voltaic conversion layer includes silicon carbide having a band gap of 2 eV or larger. In some embodiments, at least one layer of the first and the second photo-voltaic conversion layers includes silicon carbide. In some embodiments, at least one layer of the first and the second the photo-voltaic conversion layer formed contains aluminum. In some embodiments, the first high-resistivity photo-voltaic conversion layer is formed by heating processing of 800 K or higher. In some embodiments, at least one layer of the photo-voltaic conversion layer is formed by sputtering, CVD, or evaporation. In some embodiments, at least another layer is formed after at least one layer of the photo-voltaic conversion layer is formed by the heat processing of 800 K or higher, and also heating processing of 700 K or lower is performed. In some embodiments, at least one layer of the photo-voltaic conversion layer is formed by a sputtering method using a silicon carbide target containing 80 ppm or more of aluminum. In some embodiments, at least one layer of the photo-voltaic conversion layer is formed by a sputtering method using a silicon carbide target containing boron. In some embodiments, at least one layer of the photo-voltaic conversion layer is formed by a sputtering method using a silicon carbide target containing gallium.

Other features, aspects and objects of the invention can be obtained from a review of the figures and the claims. It is to be understood that other embodiments of the invention can be developed and fall within the spirit and scope of the invention and claims.

The foregoing description of preferred embodiments of the present invention has been provided for the purposes of illustration and description. It is not intended to be exhaustive or to limit the invention to the precise forms disclosed. Various additions, deletions and modifications are contemplated as being within its scope. The scope of the invention is, therefore, indicated by the appended claims rather than the foregoing description. Further, all changes which may fall within the meaning and range of equivalency of the claims and elements and features thereof are to be embraced within their scope.

What is claimed is:

1. A heterojunction semiconductor, comprising:
a bulk layer of semiconductor material;
a high-resistivity layer provided over the bulk layer; and
a microcrystalline β-SiC layer provided over the high-resistivity layer,
whereby the bulk layer, the high-resistivity layer, the microcrystalline β-SiC layer are
created by performing the steps of:
exposing of a top surface of a single-piece semiconductor material to an energy source, whereby the energy source causes heating of a portion of the single-piece semiconductor material;
ceasing exposure of the top surface of the single-piece semiconductor material to the energy source, whereby the exposing step and the ceasing step cause the single-piece semiconductor material to transform into the structure comprising the bulk layer, the high-resistivity layer, and a plurality of SiC seed crystals at the surface of the high-resistivity layer;
forming a SiC layer over the high-resistivity layer having the plurality of SiC seed crystals; and
performing a first annealing the structure comprising the bulk layer, the high-resistivity layer, the plurality of SiC seed crystals at the surface of the high-resistivity layer, and the SiC layer,
whereby the annealing causes the SiC layer to covert into the microcrystalline β-SiC layer.

2. The heterojunction semiconductor of claim 1, further performing the steps of:
performing a second annealing of the structure comprising the bulk layer, the high-resistivity layer and the microcrystalline β-SiC layer to reduce crystalline defects in the microcrystalline β-SiC layer.

3. The heterojunction semiconductor of claim 2, wherein performing the second annealing occurs at a temperature that is lower than the temperature of the first annealing.

4. The heterojunction semiconductor of claim 1, wherein performing the first annealing occurs at a temperature of at least 1300 K.

5. The heterojunction semiconductor of claim 1, wherein the steps of exposing and ceasing occurs in a vacuum.

6. The heterojunction semiconductor of claim 1, wherein performing the first annealing occurs for a duration of at least 2 hours.

7. The heterojunction semiconductor of claim 1, whereby the high-resistivity layer has a resistivity of at least ten times greater than the resistivity of the bulk layer.

8. The heterojunction semiconductor of claim 1, wherein single-piece semiconductor material comprises silicon, the silicon having the impurity of carbon.

9. The heterojunction semiconductor of claim 1, wherein the band gap of the bulk layer is smaller than the band gap the microcrystalline β-SiC layer.

10. The heterojunction semiconductor of claim 1, wherein performing the first annealing occurs at a temperature of at least 1500 K, and wherein the forming step comprises sputtering using a SiC target with p-type dopant.

11. The heterojunction semiconductor of claim 1, wherein the heterojunction semiconductor produces photovoltaic effects when exposed to light.

12. A photovoltaic device using the heterojunction semiconductor according to claim 1, the photovoltaic device comprising:
the heterojunction semiconductor;
a bottom electrode provided under the heterojunction semiconductor; and
a top electrode provided over the heterojunction semiconductor.

13. A method for manufacturing a heterojunction semiconductor, comprising a transformative process that is caused by performing the steps of:
exposing of a top surface of a single-piece semiconductor material to an energy source, whereby the energy source causes heating of a portion of the single-piece semiconductor material; and
ceasing exposure of the top surface of the single-piece semiconductor material to the energy source, whereby the exposing step and the ceasing step cause the single-piece semiconductor material to transform into the structure comprising:
a bulk layer of semiconductor material;
a high-resistivity layer; and
a plurality of SiC seed crystals at the surface of the high-resistivity layer;
further comprising the steps of:
forming a SiC layer over the high-resistivity layer having the plurality of SiC seed crystals; and
performing a first annealing the structure comprising the bulk layer, the high-resistivity layer, the plurality of SiC seed crystals at the surface of the high-resistivity layer, and the SiC layer,
whereby the annealing causes the SiC layer to covert into a microcrystalline β-SiC layer.

14. The method of claim 13, further performing the steps of:
performing a second annealing of the structure comprising the bulk layer, the high-resistivity layer and the microcrystalline β-SiC layer to reduce crystalline defects in the microcrystalline β-SiC layer.

15. The method of claim 14, wherein performing the second annealing occurs at a temperature that is lower than the temperature of the first annealing.

16. The method of claim 13, wherein performing the first annealing occurs at a temperature of at least 1300 K.

17. The method of claim 13, wherein the steps of exposing and ceasing occurs in a vacuum.

18. The method of claim 13, wherein performing the first annealing occurs for a duration of at least 2 hours.

19. The method of claim 13, whereby the high-resistivity layer has a resistivity of at least ten times greater than the resistivity of the bulk layer.

20. The method of claim 13, wherein single-piece semiconductor material comprises silicon, the silicon having the impurity of carbon.

21. The method of claim 13, wherein the band gap of the bulk layer is smaller than the band gap the microcrystalline β-SiC layer.

22. The method of claim 13, wherein performing the first annealing occurs at a temperature of at least 1500 K, and wherein the forming step comprises sputtering using a SiC target with p-type dopant.

23. The method of claim 13, wherein the heterojunction semiconductor produces photovoltaic effects when exposed to light.
